(19) United States
(12) Patent Application Publication
(10) Pub. No.: US 2025/0391687 A1
(43) Pub. Date: Dec. 25, 2025

(54) SUBSTRATE TREATING SYSTEM

(71) Applicant: SEMES CO., LTD., Chungcheongnam-do (KR)

(72) Inventors: Sung Pil KIM, Hwaseong-si (KR); Sung Hyun KIM, Hwaseong-si (KR)

(21) Appl. No.: 19/233,176

(22) Filed: Jun. 10, 2025

(30) Foreign Application Priority Data
Jun. 20, 2024 (KR) 10-2024-0080506

(51) Int. Cl. H01L 21/673; H01L 21/677

(52) U.S. Cl. CPC H01L 21/67389; H01L 21/67706; H01L 21/67724; H01L 21/67733

(57) ABSTRACT

Disclosed is a substrate treating system including: a substrate treating apparatus including a load port on which a receiving container or accommodating a substrate is placed and a treating module for performing a predetermined process on the substrate; a cleaning container including a cleaning module for cleaning the load port; a transfer device for transferring the receiving container and the cleaning container to the load port; and a controller for controlling the substrate treating apparatus and the transfer device, in which the transfer device includes: a rail provided along a ceiling; and a transfer vehicle that travels along the rail and transfers the receiving container and the cleaning container to the road port.

### CROSS-REFERENCE TO RELATED APPLICATIONS

This application claims priority to and the benefit of Korean Patent Application No. 10-2024-0080506 filed in the Korean Intellectual Property Office on Jun. 20, 2024, the entire contents of which are incorporated herein by reference.

### TECHNICAL FIELD

The present invention relates to a substrate treating system.

### BACKGROUND ART

In general, semiconductor devices, such as integrated circuit elements, may be formed by a series of repetitive fine treatment processes on a substrate, such as a silicon wafer. For example, various types of semiconductor devices may be formed on a substrate by repeatedly performing a deposition process to form a thin film on the substrate, an etching process to form the thin film on the substrate into specific patterns, an ion implantation process or diffusion process to impart electrical properties to the patterns, a cleaning and rinsing process to remove impurities from the substrate on which the patterns are formed, and the like.

The foregoing semiconductor manufacturing processes are carried out in high cleanliness process chambers, where the substrates are received in receiving containers, such as Front Open Unified Pods (FOUPs), and transported to a process facility where the semiconductor manufacturing process takes place.

The receiving container is transferred between a stocker and a load port by a transfer vehicle. When the receiving container is transferred to the load port, particles may be attached to the outer wall of the load port, which may cause contamination of the load port.

### SUMMARY OF THE INVENTION

The present invention has been made in an effort to provide a substrate treating system capable of removing particles on a load port.

The objectives of the present disclosure are not limited thereto and other objectives not stated herein may be clearly understood by those skilled in the art from the following description.

An exemplary embodiment of the present invention, a substrate treating system comprising: a substrate treating apparatus including a load port on which a receiving container or accommodating a substrate is placed and a treating module for performing a predetermined process on the substrate; a cleaning container including a cleaning module for cleaning the load port; a transfer device for transferring the receiving container and the cleaning container to the load port; and a controller for controlling the substrate treating apparatus and the transfer device, wherein the transfer device may include: a rail provided along a ceiling; and a transfer vehicle that travels along the rail and transfers the receiving container and the cleaning container to the road port.

According to the embodiment of the present invention, the cleaning container includes: a body with an open interior space on one side; a door for opening and closing the interior space; and a separation plate provided to surround a side of the stage on which the receiving container is placed in the load port when the cleaning container is placed on the load port, and the cleaning module may be provided in the interior space.

According to the embodiment of the present invention, the separation plate may be provided in a ring shape.

According to the embodiment of the present invention, the separation plate is provided to be movable between a standby position and a separation position with respect to the body, the standby position is higher than the separation position, and when the cleaning container is placed on the load port, the separation plate may surrounds the stage at the separation position.

According to the embodiment of the present invention, the cleaning container further may include a driver that moves the separation plate between the standby position and the separation position.

According to the embodiment of the present invention, the cleaning module further includes: a first inhaler that sucks particles on the stage when the cleaning container is placed on the load port; and a first filter installed on a bottom surface of the body, and the first inhaler may be located inside the body.

According to the embodiment of the present invention, the substrate treating apparatus further includes a door opener for opening and closing a door of the receiving container, the cleaning module further includes: a second inhaler that sucks particles on the door opener when the cleaning container is placed on the load port; and a second filter disposed between the second inhaler and the door, and the second inhaler may be located inside the body.

According to the embodiment of the present invention, the cleaning container further includes a control module for controlling the driver, the first inhaler, and the second inhaler, and when the cleaning container is placed on the load port, the control module instructs the driver to move the separation plate from the standby position to the separation position and may instructs the first inhaler to suck the particles on the stage.

According to the embodiment of the present invention, the control module instructs the driver to move the separation plate from the separation position to the standby position and may instructs the second inhaler to suck the particles on the door opener.

According to the embodiment of the present invention, the controller determines whether cleaning is required in the load port, and when it is determined that the cleaning is required in the load port, the controller may controls the transfer vehicle to move the cleaning container to the load port.

According to the embodiment of the present invention, the controller may determines whether the cleaning is required in the load port based on the number of substrates transferred to the load port.

According to the embodiment of the present invention, the controller may determines whether the cleaning is required in the load port based on whether a preset time has elapsed since previous cleaning of the load port was completed.

An exemplary embodiment of the present invention, a cleaning container for cleaning a load port, the cleaning container comprising: a body with an open interior space on one side; a door for opening and closing the interior space; and a cleaning module provided in the interior space, wherein the body may include, a first hole provided on a lower surface of the body; and a separation plate provided to surround a side of a stage of the load port by moving up and down.

According to the embodiment of the present invention, the separation plate is provided to be movable between a standby position and a separation position with respect to the body, the standby position is higher than the separation position, and when the cleaning container is placed on the load port, the separation plate may surrounds the stage at the separation position.

According to the embodiment of the present invention, the cleaning container further may include a driver that moves the separation plate between the standby position and the separation position.

According to the embodiment of the present invention, the cleaning module includes: a first inhaler that sucks particles on the stage through the first hole when the cleaning container is placed in the load port; and a first filter that filters the particles sucked by the first inhaler, and the first inhaler is located inside the body, and the first filter may be installed on a bottom surface of the body.

According to the embodiment of the present invention, the door includes a second hole, the cleaning module further includes: a second inhaler that sucks particles on a door opener of the load port through the second hole when the cleaning container is placed in the load port; and a second filter that filters particles sucked by the second inhaler, and the second filter may be provided between the door and the second inhaler.

An exemplary embodiment of the present invention, a substrate treating system comprising: a substrate treating apparatus including a load port on which a receiving container accommodating a substrate is placed and a treating module for performing a predetermined process on the substrate; a cleaning container including a cleaning module that cleans the load port; and a stocker in which the receiving container and the cleaning container wait; a transfer device for transferring the receiving container and the cleaning container between the load port and the stocker; and a controller for controlling the substrate treating apparatus and the transfer device, wherein the transfer device includes: a rail provided along a ceiling; and a transfer vehicle that travels along the rail and transfers the receiving container and the cleaning container between the road port and the stocker, the cleaning container includes: a body with an open interior space on one side; a door for opening/closing the interior space; a separation plate provided to surround a side of a stage on which the receiving container is placed in the load port when the cleaning container is placed on the load port, the separation plate being provided to be movable between a standby position and a separation position with respect to the body; and a driver that moves the separation plate between the standby position and the separation position, the cleaning module is provided in the interior space, the standby position is higher than the separation position, and when the cleaning container is placed on the load port, the separation plate may surrounds the stage at the separation position.

According to the embodiment of the present invention, the separation plate may be provided in a ring shape.

According to the embodiment of the present invention, the substrate treating apparatus further includes a door opener for opening and closing a door of the receiving container, the cleaning module further includes: a first inhaler that sucks particles on the stage when the cleaning container is placed on the load port; a first filter installed on a bottom surface of the body; a second inhaler that sucks particles on the door opener when the cleaning container is placed on the load port; and a second filter disposed between the second inhaler and the door, and the first inhaler and the second inhaler may be located inside the body.

According to the embodiment of the present invention, particles on the load port may be removed by providing a separate cleaning container.

According to the embodiment of the present invention, when a cleaning container cleans a load port, particles of the stage may be prevented from leaking to the outside by closing both sides of the stage.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram illustrating a substrate treating system viewed from above according to an embodiment of the present invention.

FIGS. 2 to 3 are top plan views schematically illustrating a substrate treating apparatus according to an embodiment of the present invention.

FIG. 4 is a top plan view of a cleaning container according to an embodiment of the present invention.

FIG. 5 is a top plan view of a cleaning container according to an embodiment of the present invention as viewed from below.

FIG. 6 is a flowchart illustrating an operating method of the cleaning container according to an embodiment of the present invention.

FIGS. 7 to 13 are diagrams illustrating the operating method of the cleaning container according to the embodiment of the present invention.

FIG. 14 is a top plan view of a cleaning container according to another embodiment of the present invention as viewed from below.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

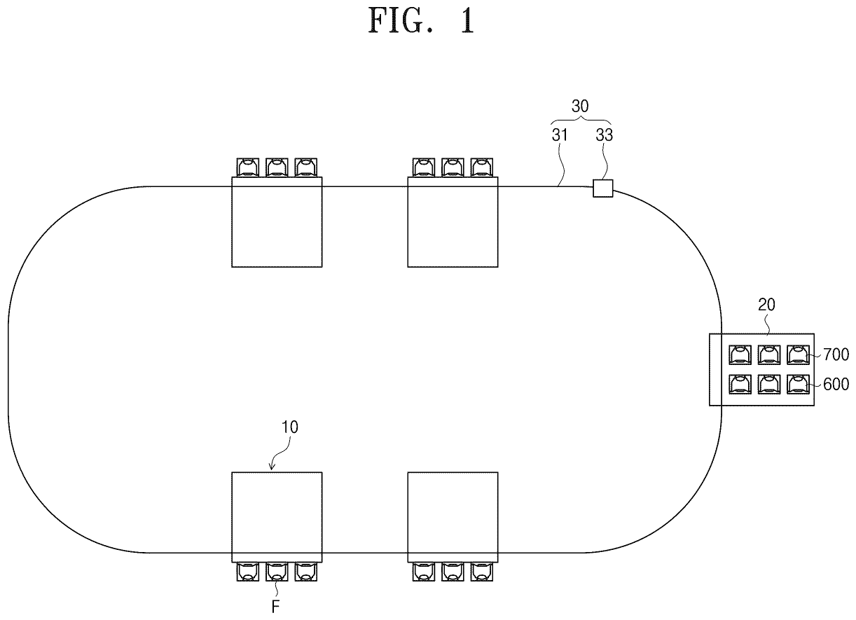

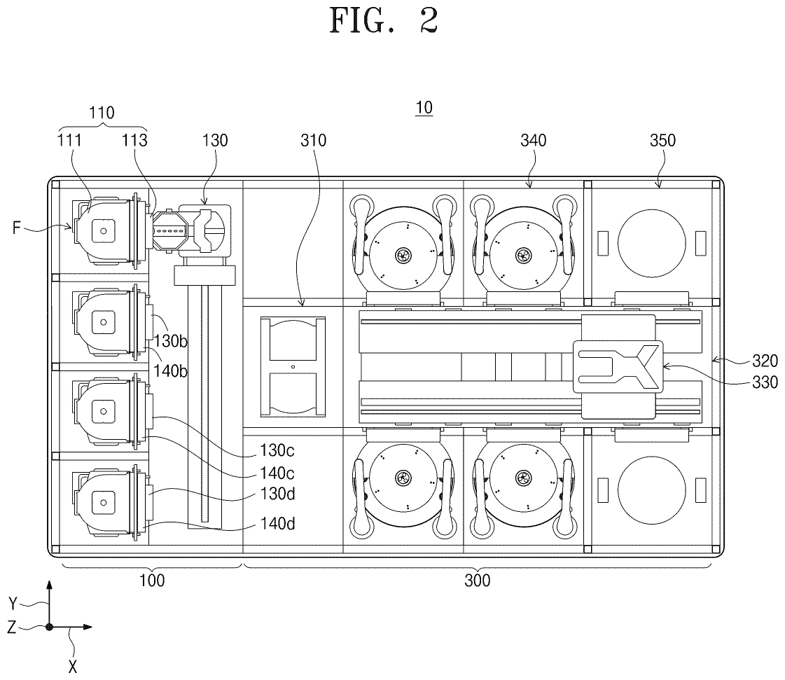

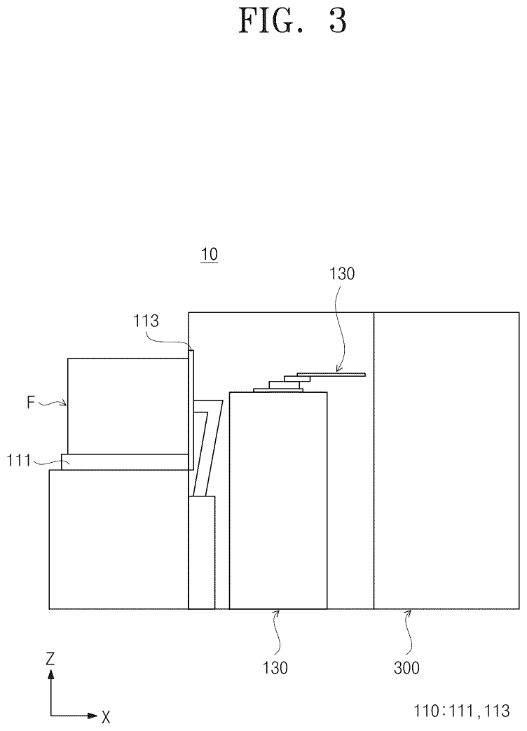

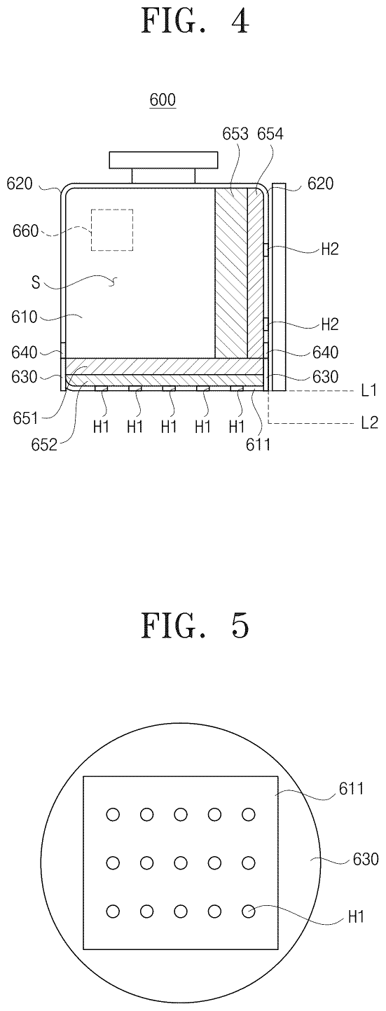

FIG. 1 is a diagram illustrating a substrate treating system viewed from above according to an embodiment of the present invention. FIGS. 2 to 3 are top plan views schematically illustrating a substrate treating apparatus according to an embodiment of the present invention. FIG. 4 is a top plan view of a cleaning container according to an embodiment of the present invention. FIG. 5 is a top plan view of a cleaning container according to an embodiment of the present invention as viewed from below.

Referring to FIG. 1, a substrate treating system 1 according to an embodiment of the present invention may include a substrate treating apparatus 10, a stocker 20 for loading and storing containers, and a transfer device 30 for transferring containers between the substrate treating apparatus 10 and the stocker 20.

Referring to FIGS. 2 to 3, the substrate treating apparatus 10 may include an index unit 100 and a treating unit 300. When viewed from above, the index unit 100 and the treating unit 300 are disposed in one direction. Hereinafter, a direction in which the index module 100 and the treating unit 300 are arranged is referred to as a first direction X, and when viewed from above, a direction perpendicular to the first direction X is referred to as a second direction Y, and a direction perpendicular to both the first direction X and the second direction Y is referred to as a third direction Z.

The index unit 100 may include a load port 110 and a first transfer robot 130. The load port 110 may include a stage 111 and a door opener 113.

A container may be mounted on the stage 111. The container may include a cleaning container 600 for cleaning the load port 110 and a receiving container 700 configured to accommodate the substrate W.

Referring to FIG. 4, the cleaning container 600 may include a body 610, a door 620 for opening and closing an interior space S, a separation plate 630, a driver 640, a cleaning module 650, and a control module 660.

The body 610 may have the interior space S having one side open. A first hole H1 may be formed in a bottom surface 611 of the body 610.

The door 620 may open and close the interior space S of the body 610. A second hole H2 may be formed in the door 620.

The separation plate 630 may be provided to be movable between a standby position L1 and a separation position L2 with respect to the body 610. The standby position L1 may be higher than the separation position L2.

Referring to FIG. 5, in the embodiment, the separation plate 630 may be provided in a ring shape. When the cleaning container 600 is placed on the stage 111, the separation plate 630 may move from the standby position L1 to the separation position L2. When the separation plate 630 moves to the separation position L2, the separation plate 630 may surround the side surfaces of the stage 111. In the embodiment, the separation plate 630 may surround all four surfaces of the stage 111. In another embodiment, the separation plate 630 may surround two or three surfaces of the stage 111.

The driver 640 may move the separation plate 630 between the standby position L1 and the separation position L2.

The cleaning module 650 may include a first inhaler 651, a first filter 652, a second inhaler 653, and a second filter 654.

The first inhaler 651 may be provided in the interior space S. When the cleaning container 600 is placed on the stage 111, the first inhaler 651 may suck particles on the stage 111 through the first hole H1.

The first filter 652 may be installed on the bottom surface 611. The first filter 652 may be disposed between the first inhaler 651 and the bottom surface 611. The first filter 652 may filter particles sucked through the first inhaler 651.

The second inhaler 653 may be provided in the interior space S. When the cleaning container 600 is placed on the stage 111, the first inhaler 651 may suck particles on the door opener 113 through the second hole H2.

The second filter 654 may be disposed between the second inhaler 653 and the door 620. The second filter 654 may filter particles sucked through the second inhaler 653.

The control module 660 may control the driver 640, the first inhaler 651, and the second inhaler 653. The control module 660 may include a process controller made of a microprocessor (computer), a user interface made of a keyboard that performs a command input operation, a display, or the like, and a memory in which a control program or a program for executing processing to each component according to various data and processing conditions is stored.

When the receiving container 700 is seated on the stage 111, the door opener 113 may open the door of the receiving container 700.

The first transfer robot 130 may transfer the substrate W accommodated in the receiving container 700 from the receiving container 700 to the treating unit 300, or transfer the treatment-completed substrate W from the treating unit 300 to the receiving container 700.

The treating unit 300 may include a buffer chamber 310, a transfer chamber 320, a second transfer robot 330, a liquid treating chamber 340, and a drying chamber 350.

The buffer chamber 310 may provide a space for the substrate W being loaded into the treating unit 300 and the substrate W being unloaded from the treating unit 300 to temporarily stay. The liquid treating chamber 340 performs a liquid treating process of treating the substrate W with a liquid by supplying a liquid onto the substrate W. The drying chamber 350 performs a drying process of removing the liquid residual on the substrate W. The transfer chamber 320 may transfer the substrate W between the buffer chamber 310, the liquid treating chamber 340, and the drying chamber 350.

The buffer chamber 310 may include a plurality of buffers 312 in which the substrate W is placed.

The plurality of buffers 312 may be spaced apart from each other along the third direction Z. The plurality of buffers 312 may be substrate holders that support a bottom surface of the substrate W. The plurality of buffers 312 may be provided in the shape of support shelves that support the bottom surface of the substrate W.

The buffer chamber 310 has an open front face and rear face. The front face is a surface facing the index unit 100, and the rear face is a surface facing the transfer chamber 320. The first transfer robot 130 may access the buffer chamber 310 through the front face, and the second transfer robot 330 may access the buffer chamber 310 through the rear face.

A longitudinal direction of the transfer chamber 30 may be provided in the first direction X. The buffer chamber 310 may be disposed between the index unit 100 and the transfer chamber 320. The liquid treating chamber 340 and the drying chamber 350 may be disposed on a side portion of the transfer chamber 320. The liquid treating chamber 340 and the transfer chamber 320 may be disposed along the second direction Y. The drying chamber 350 and the transfer chamber 320 may be disposed along the second direction Y. The buffer chamber 310 may be positioned at one end of the transfer chamber 320.

The second transfer robot 330 may be provided to the transfer chamber 320. The second transfer robot 330 may transfer the substrate W between the buffer chamber 310 and the liquid treating chamber 340.

For example, the liquid treating chambers 340 may be disposed on opposite sides of the transfer chamber 320, the drying chambers 350 may be disposed on opposite sides of the transfer chamber 320, and the liquid treating chambers 340 may be disposed closer to the buffer chamber 310 than the drying chambers 350. At one side of the transfer chamber 320, the liquid treating chambers 340 may be provided in an arrangement of A×B (each of A and B is 1 or a natural larger than 1) in the first direction X and the third direction Z. Further, at one side of the transfer chamber 320, the drying chambers 350 may be provided in number of C×D (each of C and D is 1 or a natural number larger than 1) in the first direction X and the third direction Z. Unlike the above description, only the liquid treatment chambers 340 may be provided at one side of the transfer chamber 320, and only the drying chambers 350 may be provided at the other side thereof.

The transfer device 30 may transfer a container between the substrate treating apparatus 10 and the stocker 20. The transfer device 200 may include a rail 31 and a transfer vehicle 33. The rail 31 provides a path on which the transfer vehicle 33 to be described later travels. The rail 31 may be fixedly installed on the ceiling of the semiconductor manufacturing line. Although FIG. 1 illustrates the rail 31 in a generally hexagonal shape, this is the embodiment, and the shape of the rail 31 may be variously modified to a circular shape, a rectangular shape, and the like. The rail 31 may be provided along the ceiling of the semiconductor manufacturing line and installed so as to check the substrate treating apparatus 30 from the top. The installation range of the rail 31 may be arranged in a wide area so as to view the substrate treating apparatus 10 as a whole.

The transfer vehicle 33 may be an overhead hoist vehicle. The transfer vehicle 33 may grip the container. The transfer vehicle 33 may travel along a predetermined route along the rail 31. The transfer vehicle 33 may travel along the rail 31 at a predetermined speed.

The controller 40 may determine whether cleaning is required in the load port 110, and control the transfer device 30 based on the determination. The controller 40 may be configured to be the same as or similar to the control module 660.

The controller 40 may determine whether cleaning is required in the load port 110 based on the number of substrates W transferred to the load port 110 through the receiving container 700. In the embodiment, the controller 40 may determine that cleaning is required in the load port 110 when the number of substrates W transferred to the load port 110 is greater than or equal to a preset value.

In another embodiment, the controller 40 may determine whether cleaning is required in the load port 110 based on whether a preset time has elapsed since the previous cleaning of the load port 110 is completed. When the preset time has elapsed since the previous cleaning of the load port 110 is completed, the controller 40 may determine that cleaning is required in the load port 110.

In another embodiment, the controller 40 may determine whether cleaning is required in the load port 110 based on the number of receiving containers 700 placed on the load port 110 since the previous cleaning of the load port 110 is completed. The controller 40 may determine that cleaning is required in the load port 110 when the number of receiving containers 700 placed on the load port 110 is greater than or equal to a preset value since the previous cleaning of the load port 110 is completed.

When it is determined that cleaning is required in the load port 110, the controller 40 may instruct the transfer vehicle 33 to transfer the cleaning container 600 from the stocker 20 to the load port 110.

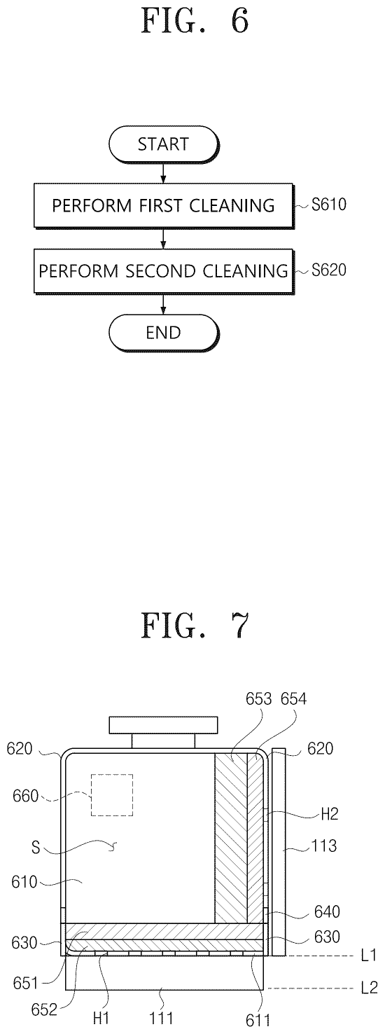

FIG. 6 is a flowchart illustrating an operating method of the cleaning container according to an embodiment of the present invention.

FIGS. 7 to 13 are diagrams illustrating an operating method of the cleaning container according to the embodiment of the present invention.

Referring to FIG. 6, the cleaning container may perform first cleaning (S610). Referring to FIG. 7, the control module 660 may determine whether the cleaning container 600 is placed on the stage 111.

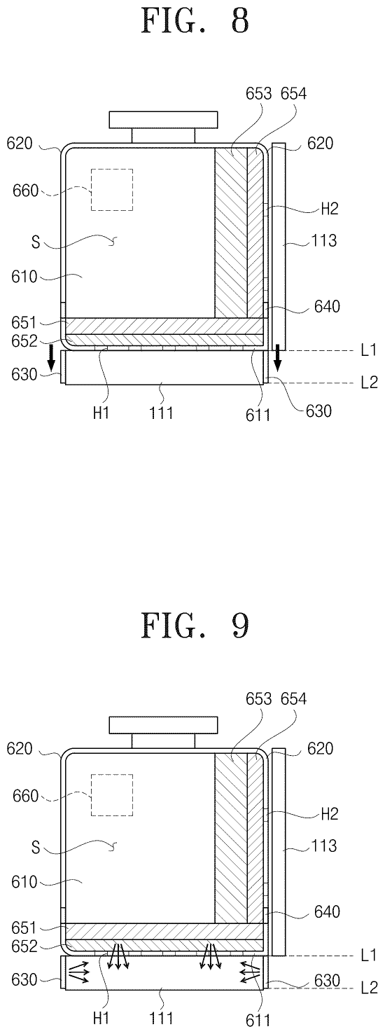

Referring to FIG. 8, when the cleaning container 600 is placed on the stage 111, the control module 660 may instruct the driver 640 to move the separation plate 630 from the standby position L1 to the separation position L2.

Referring to FIG. 9, when the separation plate 630 moves to the separation position L2, the side surface of the stage 111 may be closed. The control module 660 may instruct the first inhaler 651 to suck the particles on the stage 111 for a preset time. The first inhaler 651 may suck the particles on the stage 111 in a state in which the side surface of the stage 111 is closed by the separation plate 630. The first inhaler 651 may suck the particles on the stage 111 through the first hole H1. Accordingly, it is possible to prevent particles from flowing out of the side surface or the outside of the stage 111 during the suction process.

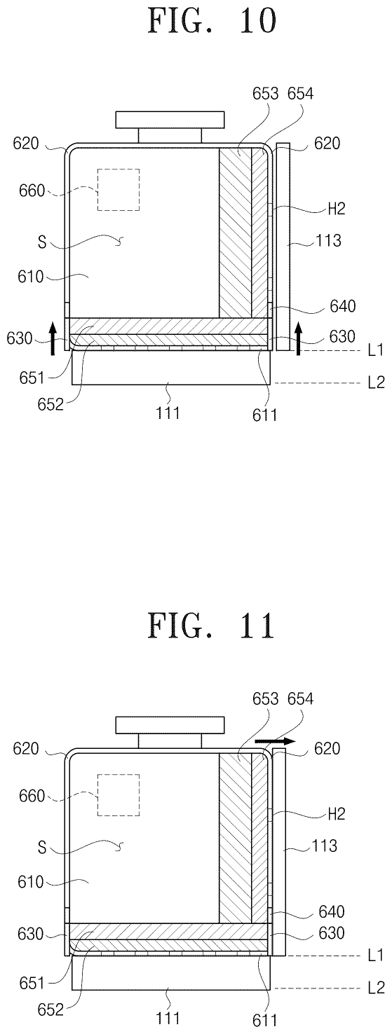

The cleaning container may perform second cleaning (S620). Referring to FIG. 10, when a preset time has elapsed from the start of the first cleaning, the control module 660 may instruct the driver 640 to move the separation plate 630 from the separation position L2 to the standby position L1, and may move the separation plate 630 from the separation position L2 to the standby position L1.

Referring to FIG. 11, when the separation plate 630 is moved to the standby position L1, the cleaning container 600 may be coupled to the door opener 113.

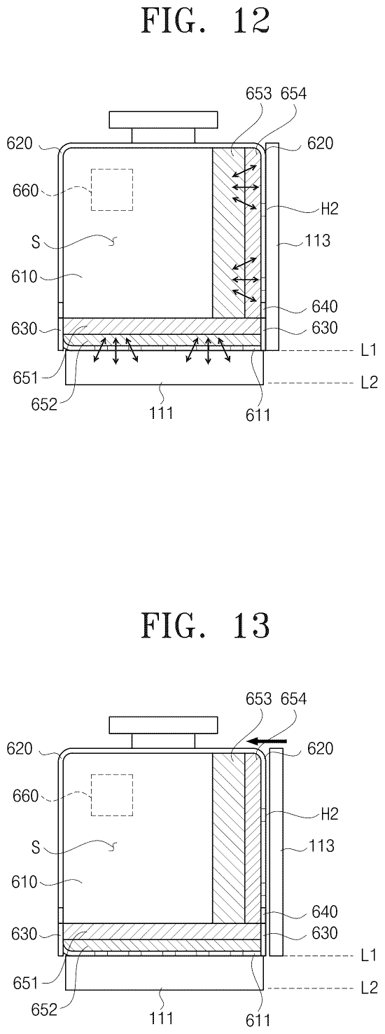

Referring to FIG. 12, the control module 660 may instruct the second inhaler 653 to suck particles on the door opener 113 for a preset time. The second inhaler 653 may suck particles on the door opener 113 through the second hole H2. Although it is illustrated that the first inhaler 651 simultaneously sucks particles on the stage 111, the control module 660 may not operate the first inhaler 651.

Referring to FIG. 13, the cleaning container 600 may release the coupling with the door opener 113.

Meanwhile, although FIG. 6 illustrates that S610 and S620 are sequentially performed, in another embodiment, S610 and S620 may be performed simultaneously. That is, the cleaning container 600 may simultaneously suck particles on the stage 111 and particles on the door opener 113.

In another embodiment, after S620 is performed, S610 may be performed. That is, the cleaning container 600 may suck particles on the stage 111 after sucking particles on the door opener 113.

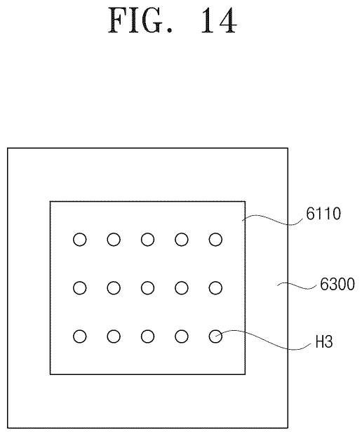

FIG. 14 is a top plan view of a cleaning container according to another embodiment of the present invention as viewed from below.

Referring to FIG. 14, a cleaning container 6000 according to another embodiment of the present invention may include a separation plate 6300 having a quadrangular shape. In the embodiment, the separation plate 6300 may surround all four surfaces of the stage 111. In another embodiment, the separation plate 6300 may surround two or three surfaces of the stage 111.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate treating system comprising:
a substrate treating apparatus including a load port on which a receiving container or accommodating a substrate is placed and a treating module for performing a predetermined process on the substrate;
a cleaning container including a cleaning module for cleaning the load port;
a transfer device for transferring the receiving container and the cleaning container to the load port; and
a controller for controlling the substrate treating apparatus and the transfer device,
wherein the transfer device includes:
a rail provided along a ceiling; and
a transfer vehicle that travels along the rail and transfers the receiving container and the cleaning container to the road port.

2. The substrate treating system of claim 1, wherein the cleaning container includes:
a body with an open interior space on one side;
a door for opening and closing the interior space; and
a separation plate provided to surround a side of the stage on which the receiving container is placed in the load port when the cleaning container is placed on the load port, and
the cleaning module is provided in the interior space.

3. The substrate treating system of claim 2, wherein the separation plate is provided in a ring shape.

4. The substrate treating system of claim 2, wherein the separation plate is provided to be movable between a standby position and a separation position with respect to the body,
the standby position is higher than the separation position, and
when the cleaning container is placed on the load port, the separation plate surrounds the stage at the separation position.

5. The substrate treating system of claim 4, wherein the cleaning container further includes a driver that moves the separation plate between the standby position and the separation position.

6. The substrate treating system of claim 5, wherein the cleaning module further includes:
a first inhaler that sucks particles on the stage when the cleaning container is placed on the load port; and
a first filter installed on a bottom surface of the body, and
the first inhaler is located inside the body.

7. The substrate treating system of claim 6, wherein the substrate treating apparatus further includes a door opener for opening and closing a door of the receiving container,
the cleaning module further includes:
a second inhaler that sucks particles on the door opener when the cleaning container is placed on the load port; and
a second filter disposed between the second inhaler and the door, and
the second inhaler is located inside the body.

8. The substrate treating system of claim 7, wherein the cleaning container further includes a control module for controlling the driver, the first inhaler, and the second inhaler, and
when the cleaning container is placed on the load port, the control module instructs the driver to move the separation plate from the standby position to the separation position and instructs the first inhaler to suck the particles on the stage.

9. The substrate treating system of claim 8, wherein the control module instructs the driver to move the separation plate from the separation position to the standby position and instructs the second inhaler to suck the particles on the door opener.

10. The substrate treating system of claim 1, wherein the controller determines whether cleaning is required in the load port, and
when it is determined that the cleaning is required in the load port, the controller controls the transfer vehicle to move the cleaning container to the load port.

11. The substrate treating system of claim 10, wherein the controller determines whether the cleaning is required in the load port based on the number of substrates transferred to the load port.

12. The substrate treating system of claim 10, wherein the controller determines whether the cleaning is required in the load port based on whether a preset time has elapsed since previous cleaning of the load port was completed.

13. A cleaning container for cleaning a load port, the cleaning container comprising:
a body with an open interior space on one side;
a door for opening and closing the interior space; and
a cleaning module provided in the interior space,
wherein the body includes:
a first hole provided on a lower surface of the body; and
a separation plate provided to surround a side of a stage of the load port by moving up and down.

14. The cleaning container of claim 13, wherein the separation plate is provided to be movable between a standby position and a separation position with respect to the body,
the standby position is higher than the separation position, and
when the cleaning container is placed on the load port, the separation plate surrounds the stage at the separation position.

15. The cleaning container of claim 14, wherein the cleaning container further includes a driver that moves the separation plate between the standby position and the separation position.

16. The cleaning container of claim 13, wherein the cleaning module includes:
a first inhaler that sucks particles on the stage through the first hole when the cleaning container is placed in the load port; and
a first filter that filters the particles sucked by the first inhaler, and
the first inhaler is located inside the body, and
the first filter is installed on a bottom surface of the body.

17. The cleaning container of claim 16, wherein the door includes a second hole, the cleaning module further includes:
a second inhaler that sucks particles on a door opener of the load port through the second hole when the cleaning container is placed in the load port; and
a second filter that filters particles sucked by the second inhaler, and
the second filter is provided between the door and the second inhaler.

18. A substrate treating system comprising:
a substrate treating apparatus including a load port on which a receiving container accommodating a substrate is placed and a treating module for performing a predetermined process on the substrate;
a cleaning container including a cleaning module that cleans the load port; and
a stocker in which the receiving container and the cleaning container wait;
a transfer device for transferring the receiving container and the cleaning container between the load port and the stocker; and
a controller for controlling the substrate treating apparatus and the transfer device,
wherein the transfer device includes:
a rail provided along a ceiling; and
a transfer vehicle that travels along the rail and transfers the receiving container and the cleaning container between the road port and the stocker,
the cleaning container includes:
a body with an open interior space on one side;
a door for opening/closing the interior space;
a separation plate provided to surround a side of a stage on which the receiving container is placed in the load port when the cleaning container is placed on the load port, the separation plate being provided to be movable between a standby position and a separation position with respect to the body; and
a driver that moves the separation plate between the standby position and the separation position,
the cleaning module is provided in the interior space,
the standby position is higher than the separation position, and
when the cleaning container is placed on the load port, the separation plate surrounds the stage at the separation position.

19. The substrate treating system of claim 18, wherein the separation plate is provided in a ring shape.

20. The substrate treating system of claim 18, wherein the substrate treating apparatus further includes a door opener for opening and closing a door of the receiving container,
the cleaning module further includes:
a first inhaler that sucks particles on the stage when the cleaning container is placed on the load port;
a first filter installed on a bottom surface of the body;
a second inhaler that sucks particles on the door opener when the cleaning container is placed on the load port; and
a second filter disposed between the second inhaler and the door, and
the first inhaler and the second inhaler are located inside the body.
